(19) United States
(12) Patent Application Publication
(10) Pub. No.: US 2025/0093778 A1
(43) Pub. Date: Mar. 20, 2025

(54) METHOD FOR AREA SELECTIVE DEPOSITION ON EXTREME ULTRA-VIOLET (EUV) PHOTORESISTS

(71) Applicant: Tokyo Electron Limited, Tokyo (JP)

(72) Inventors: Lior Huli, Albany, NY (US); Kandabara Tapily, Albany, NY (US)

(21) Appl. No.: 18/369,323

(22) Filed: Sep. 18, 2023

(51) Int. Cl. G03F 7/09; G03F 7/00; G03F 7/075; G03F 7/16

(52) U.S. Cl. CPC G03F 7/094; G03F 7/075; G03F 7/167; G03F 7/70033

(57) ABSTRACT

Embodiments of processes and methods are disclosed herein that utilize a combination of extreme ultra-violet (EUV) lithography and area selective deposition (ASD) processes to form an EUV photoresist pattern on at least one underlayer formed above a semiconductor substrate. In the disclosed embodiments, a photoresist film is deposited on the underlayer(s) and patterned using EUV lithography to form an EUV photoresist pattern on the underlayer(s). After the photoresist film is deposited and patterned, an ASD process is used to selectively deposit a topcoat film on the EUV photoresist pattern without depositing the topcoat film on exposed surfaces of the underlayer(s) not covered by the EUV photoresist pattern. An inhibition layer is provided on, or within, the underlayer(s) before, during or after EUV lithography to enable area selective deposition of the topcoat film on the EUV photoresist pattern.

### TECHNICAL FIELD

The present disclosure relates to extreme ultraviolet (EUV) lithography, and in particular embodiments, to EUV photoresists and methods of formation thereof.

### BACKGROUND

Generally, a semiconductor device, such as an integrated circuit (IC) is fabricated by sequentially depositing and patterning layers of dielectric, conductive, and semiconductor materials over a semiconductor substrate to form a network of electronic components and interconnect elements (e.g., transistors, resistors, capacitors, metal lines, contacts, and vias) integrated in a monolithic structure. At each successive technology node, the minimum feature sizes are shrunk to reduce cost by roughly doubling the component packing density.

A common patterning method is to use a photolithography process to expose a coating of photoresist film over a target layer to a pattern of actinic radiation and then transfer the relief pattern to the target layer or an underlying hard mask layer formed over the target layer. With this technique, the minimum feature size would be limited by the resolution of the optical system. Scaling of feature sizes for advanced technology nodes is driving lithography to improve resolution. For sub-10 nm technology nodes (for example, 7 nm and 5 nm technology nodes), 13.5 nm extreme ultraviolet (EUV) lithography is commonly used to pattern a photoresistive film with EUV radiation.

EUV lithography techniques offer significant advantages in patterning sub-10 nm features with its high optical resolution. However, one major engineering challenge for EUV lithography is that photoresists developed for conventional photolithography systems may not satisfy the cost and/or quality requirements for patterning sub-10 nm features. For example, chemically amplified resist (CAR) and similar polymer resists, which are commonly used in 193 nm lithography, are typically produced using liquid based spin-on techniques that consume a significant amount of complex metal cluster precursors, resulting in very high cost. CARs also tend to have low absorption coefficients at 13.5 nm, and as a result, suffer poor sensitivity. Further, the diffusion of photo-activated species in CARs may cause blurring and increase line-edge roughness (LER) in the subsequently formed pattern.

Metal-oxide photoresists are attracting attention for use in EUV lithography due to the high etch resistance/selectivity and photo reactivity to EUV of such resists. In a typical EUV lithography process, a wet or dry process may be used to deposit a metal-oxide photoresist film on at least one underlayer formed above a semiconductor substrate. The metal-oxide photoresist film can be patterned with EUV lithography to form a photoresist pattern on the underlayer(s) before an etch process is used to transfer the photoresist pattern to the underlayer(s). Although a wet or dry process may be utilized, a dry etch process (e.g., a plasma-based etch process) is typically used to transfer the metal-oxide photoresist pattern to the underlayer(s).

Challenges remain with patterning underlayers using metal-oxide photoresists and other photoresists typically utilized for EUV lithography. When relatively thin photoresist films (having a film thickness <15 nm) are used to form low aspect ratio photoresist patterns, the etch process used to transfer the photoresist pattern to the underlayer(s) may damage the photoresist pattern by significantly etching (or completely removing) portions of the thin photoresist film. In some cases, photoresist damage may be alleviated by depositing a substantially thicker photoresist film (having a film thickness >20 nm) on the underlayer(s) to form a higher aspect ratio photoresist pattern. However, patterning thick photoresist films has its own challenges, oftentimes resulting in photoresist line or pillar collapse.

With continued shrinkage of IC device feature size down to angstrom-level, conventional lithography will hit its resolution limit or become too costly to use at scale. One strategy is to relax the dependence on lithography using chemically-directed, self-aligned, selective, bottom-up patterning. At the core of this strategy is area-selective processing (ASP), which is centered on the idea of exploiting the surface chemistry of exposed material layers to drive selective processing of such layers. Area-selective processing techniques can be used to selectively deposit and/or remove material from desired areas of a patterned substrate, thereby avoiding the use of photolithography for patterning.

Area selective deposition (ASD) is one example of a bottom-up, area-selective process that provides uniform deposition of material in only desired areas of a patterned substrate. Unlike conventional deposition techniques, which are designed to achieve uniform deposition over large areas, ASD enables materials to be selectively deposited on target materials (or “growth surfaces”), while avoiding deposition on nontarget materials (or “nongrowth surfaces”). ASD can be used to selectively deposit a wide variety of materials on the target materials. For example, ASD techniques can be used to selectively deposit dielectric-on-dielectric (DoD), dielectric-on-metal (DOM), metal-on-dielectric (MoD) and metal-on-metal (MoM). Area selective deposition can be achieved using a wide variety of deposition techniques, such as chemical vapor deposition (CVD), atomic layer deposition (ALD) and molecular layer deposition (MLD), which often utilize surface modifications and vapor phase deposition to deposit material on a target area. Surface modifications are typically aimed at promoting the adsorption of precursor molecules on growth surfaces and/or suppressing the adsorption of precursor molecules on nongrowth surfaces.

FIG. 8 illustrates one example of a process flow 800 that attempts to deposit a material on a photoresist pattern formed on a semiconductor substrate 10 using area selective deposition. As shown in FIG. 8, a photoresist pattern 20 is provided on at least one underlayer 30 formed above the semiconductor substrate 10. In one example, the photoresist pattern 20 may include an EUV-active photoresist film (such as, but not limited to, a metal-oxide photoresist film), and the at least one underlayer 30 may include a variety of underlayer materials typically used for EUV patterning (such as, for example, bottom anti-reflective coating layers, hardmask layers, carbon layers and other organic and inorganic material layers).

In the process flow 800 shown in FIG. 8, the incoming photoresist pattern 20 formed on the underlayer(s) 30 includes a plurality of photoresist structures 25 having variable pitch (p₁ and p₂). When depositing the material 40 on the photoresist pattern 20 using conventional ASD techniques, the difference in pitch between the photoresist structures 25 causes significantly more of the material 40 to be deposited on/between photoresist structures 25 having larger pitch (p₂) than is deposited on/between the photoresist structures 25 having smaller pitch (p₁). This pitch dependency is a challenge in conventional ASD processes due to the inhibition/selectivity from different aspect ratio.

Accordingly, a need remains for an improved EUV photoresist and methods of forming such resists.

### SUMMARY

The present disclosure provides improved processes and methods of forming a photoresist pattern on a semiconductor substrate. More specifically, the present disclosure provides various embodiments of improved processes and methods that utilize a combination of extreme ultra-violet (EUV) lithography and area selective deposition (ASD) processes to form an EUV photoresist pattern on at least one underlayer formed above a semiconductor substrate.

In the disclosed embodiments, a photoresist film is deposited on at least one underlayer and patterned using EUV lithography to form an EUV photoresist pattern on the underlayer(s). The photoresist film deposited on the underlayer(s) is a relatively thin film having, for example, a thickness less than 15 nm. After the photoresist film is deposited and patterned, an ASD process is used to selectively deposit a topcoat film on the EUV photoresist pattern without depositing the topcoat film on exposed surfaces of the underlayer(s) not covered by the EUV photoresist pattern. The topcoat film may also be a relatively thin film having a thickness less than 10 nm. By selectively depositing the topcoat film on the EUV photoresist pattern, the topcoat film increases the aspect ratio and overall thickness of the EUV photoresist pattern initially formed on the underlayer(s).

A wide variety of ASD processes are used in the embodiments disclosed herein to selectively deposit the topcoat film on the EUV photoresist pattern. In each of the embodiments disclosed herein, an inhibition layer is provided on, or within, the underlayer(s) to enable area selective deposition of the topcoat film on the EUV photoresist pattern. The inhibition layer may be provided on, or within, the underlayer(s) before, during or after EUV lithography is used to create the EUV photoresist pattern. When ASD is used to selectively deposit the topcoat film on the EUV photoresist pattern, the inhibition layer reduces (or substantially prevents) the topcoat film from being deposited on exposed surfaces of the underlayer(s). In some embodiments, the inhibition layer may prevent deposition on the underlayer(s) by providing a hydrophobic surface, which reduces (or substantially prevents) adsorption of the topcoat film on the exposed surfaces of the underlayer(s).

The processes and methods disclosed herein overcome the challenges typically faced when conventional EUV lithography or conventional ASD processes are used to form a photoresist pattern on a semiconductor substrate. As described in more detail below, the processes and methods disclosed herein avoid the photoresist damage and photoresist line or pillar collapse that often occurs during conventional EUV lithography processes, and eliminate pitch dependency problems in conventional ASD processes by utilizing a plurality of photoresist films and a combination of EUV lithography and ASD techniques to create an EUV photoresist pattern on the underlayer(s).

Various embodiments of methods are provided in the present disclosure for forming an EUV photoresist pattern on a semiconductor substrate. Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

According to one embodiment of the present disclosure, a method is provided herein for forming an extreme ultra-violet (EUV) photoresist pattern on a semiconductor substrate. The method may generally include: (a) depositing a photoresist film on an underlayer formed above the semiconductor substrate; (b) utilizing EUV lithography to pattern the photoresist film and form an EUV photoresist pattern on the underlayer; (c) providing an inhibition layer on, or within, the underlayer; and (d) selectively depositing a topcoat film on the EUV photoresist pattern. In this embodiment of the method, the inhibition layer provided on, or within, the underlayer prevents the topcoat film from being deposited on exposed surfaces of the underlayer not covered by the EUV photoresist pattern.

In some embodiments, the EUV photoresist pattern may include a plurality of photoresist structures having a pitch that is variable between the photoresist structures. In such embodiments, the inhibition layer provided on, or within, the underlayer may prevent the topcoat film from being deposited on the exposed surfaces the underlayer not covered by the EUV photoresist pattern, regardless of the pitch between the photoresist structures.

The present disclosure envisions providing the inhibition layer on, or within, the underlayer in a wide variety of ways. In a first embodiment of the method, the inhibition layer is selectively deposited on exposed surfaces of the underlayer after the photoresist film is deposited on the underlayer and patterned to form the EUV photoresist pattern. For example, the inhibition layer may be selectively deposited on the exposed surfaces of the underlayer by exposing the semiconductor substrate to an ultra-violet (UV) treatment, which enables selective adsorption of the inhibition layer on the exposed surfaces of the underlayer, rather than on the EUV photoresist pattern. In one embodiment, the UV treatment may expose the semiconductor substrate to UV radiation in the presence of an oxidizing species (for example, air, ozone or another oxidizing species having oxygen radicals) to form hydroxide groups on the exposed surfaces of the underlayer. In such an embodiment, the inhibition layer may react with the hydroxide groups to selectively adsorb onto the exposed surfaces of the underlayer without adsorbing onto the EUV photoresist pattern.

A wide variety of materials may be used to implement the underlayer and the inhibition layer in the first embodiment of the method. For example, the underlayer may comprise a hydrophilic material having a water contact angle less than or equal to 60°, and the inhibition layer may comprise a hydrophobic material having a water contact angle greater than or equal to 90°. Examples of materials suitable for use as an underlayer include, but are not limited to, amorphous carbon (a-C), silicon oxycarbide (SiOC), silicon carbide (SiC), amorphous silicon, silicon dioxide (SiO₂) and other metal containing materials having properties that provide good adhesion and allow inhibition molecules to attach to the underlayer. Examples of hydrophobic materials suitable for use as an inhibition layer include, but are not limited to, materials having relatively small molecules (e.g., short chain molecules having less than 2-3 carbon chains), materials having methyl end groups (e.g., trimethylsilyl (Si(CH₃)₃) end groups), benzene end groups or fluorocarbon end groups, and self-assembled monolayers (SAMs) having head groups tailored to the underlayer materials, such as but not limited to, silane, carboxylic or phosphonic head groups. Additional examples of hydrophilic and hydrophobic materials suitable for use in the underlayer and inhibition layer are discussed further herein.

In a second embodiment of the method, the underlayer is converted to an inhibition layer after the photoresist film is deposited on the underlayer and patterned to form the EUV photoresist pattern. For example, the semiconductor substrate may be exposed to a thermal, ultra-violet (UV) or chemical treatment to convert at least the exposed surfaces of the underlayer from a hydrophilic surface having a water contact angle less than or equal to 60° to a hydrophobic surface having a water contact angle greater than or equal to 90°. In some embodiments, the underlayer used in the second embodiment may comprise a silicon oxycarbonitride layer having a chemical formula of Si_{X}O_{Y}C_{Z}Nₐ, where 0≤x≤1, 0≤y≤1, 0≤z≤1 and 0≤a≤1.

In a third embodiment of the method, the underlayer is converted to an inhibition layer during the EUV lithography process used to pattern the photoresist film and form the EUV photoresist pattern on the underlayer. For example, the semiconductor substrate may be exposed to EUV radiation during the EUV lithography process to convert at least the exposed surfaces of the underlayer from a hydrophilic surface having a water contact angle less than 60° to a hydrophobic surface having a water contact angle greater than 90°. In some embodiments, the underlayer used in the third embodiment may comprise a silicon oxycarbonitride layer having a chemical formula of Si_{X}O_{Y}C_{Z}Nₐ, where 0≤x≤1, 0≤y≤1, 0≤z≤1 and 0≤a≤1. In some embodiments, inert gases such as nitrogen (N₂) or argon (Ar) used during the EUV exposure may induce additional surface modification.

In a fourth embodiment of the method, the underlayer formed above the semiconductor substrate includes a hydrophobic material, rather than a hydrophilic material. When a hydrophobic underlayer is utilized in the fourth embodiment, the method deposits a sacrificial hydrophilic material on the underlayer prior to depositing the photoresist film. The sacrificial hydrophilic material is a material, which has a water contact angle less than or equal to 60° and provides good adhesion for the photoresist film. After using EUV lithography to pattern the photoresist film and form the EUV photoresist pattern and before selectively depositing the topcoat film on the EUV photoresist pattern, the fourth embodiment of the method removes portions of the sacrificial hydrophilic material not covered by the EUV photoresist pattern to expose the hydrophobic underlayer. When the topcoat film is selectively deposited on the EUV photoresist pattern, the hydrophobic underlayer performs as an inhibition layer to prevent the topcoat film from being deposited on the exposed surfaces of the underlayer not covered by the EUV photoresist pattern.

A wide variety of hydrophobic underlayer materials and sacrificial hydrophilic materials can be utilized in the fourth embodiment. Examples of hydrophobic underlayer materials include, but are not limited to, carbon (C) and silicon carbide (SIC). The sacrificial hydrophilic material may include, but is not limited to, amorphous carbon (a-C), silicon oxycarbide (SiOC) or oxomethyl (CxOyHz, where 0≤x≤1, 0≤y≤1 and 0≤z≤1).

Another method is provided herein for forming an extreme ultra-violet (EUV) photoresist pattern on a semiconductor substrate in accordance with another embodiment of the present disclosure. The method may generally include: (a) depositing a photoresist film on an underlayer formed above the semiconductor substrate; (b) utilizing EUV lithography to pattern the photoresist film and form an EUV photoresist pattern on the underlayer, wherein the EUV photoresist pattern comprises a plurality of photoresist structures having a pitch that is variable between the photoresist structures; (c) selectively depositing an inhibition layer on exposed surfaces of the underlayer not covered by the EUV photoresist pattern; and (d) utilizing area selective deposition (ASD) to selectively deposit a topcoat film on the EUV photoresist pattern. In this embodiment of the method, the inhibition layer prevents the topcoat film from being deposited on the exposed surfaces of the underlayer not covered by the EUV photoresist pattern, regardless of the pitch between the photoresist structures.

A wide variety of materials may be used to implement the underlayer and the inhibition layer described in this embodiment of the method. For example, the underlayer may include a hydrophilic material having a water contact angle less than or equal to 60°, and the inhibition layer may include a hydrophobic material having a water contact angle greater than or equal to 90°. Examples of materials suitable for use as an underlayer include, but not limited to, amorphous carbon (a-C), silicon oxycarbide (SiOC), amorphous silicon, silicon dioxide (SiO₂) and other metal containing materials having properties that provide good adhesion and allow inhibition molecules to attach to the underlayer. The inhibition layer may comprise a wide variety of hydrophobic materials, such as materials having relatively small molecules, materials having methyl end groups, benzene end groups, or fluorocarbon end groups and self-assembled monolayers (SAMs) having head groups tailored to the underlayer materials, such as but not limited to, silane, carboxylic or phosphonic head groups. Additional examples of hydrophilic and hydrophobic materials suitable for use in the underlayer and inhibition layer are discussed further herein.

In some embodiments, the inhibition layer may be selectively deposited on the exposed surfaces of the underlayer by exposing the semiconductor substrate to an ultra-violet (UV) treatment, which enables selective adsorption of the inhibition layer on the exposed surfaces of the underlayer, rather than on the EUV photoresist pattern. In one embodiment, the UV treatment may expose the semiconductor substrate to UV radiation in the presence of an oxidizing species (for example, air, ozone or another oxidizing species) to form hydroxide groups on the exposed surfaces of the underlayer. In such an embodiment, the inhibition layer may react with the hydroxide groups to selectively adsorb onto the exposed surfaces of the underlayer without adsorbing onto the EUV photoresist pattern.

The photoresist film utilized in the method embodiments described above may include a wide variety of organic and inorganic photoresist film material. In some embodiments, the photoresist film may be a metal-oxide photoresist film containing an organometallic oxide. Organometallic oxides have a central metal atom bonded to an organic group or groups. In some embodiments, the photoresist film may comprise an organometallic oxide having a central metal atom selected from a group comprising tin (Sn), zirconium (Zr), indium (In), antimony (Sb), bismuth (Bi), zinc (Zn), hafnium (Hf), aluminum (Al) and combinations thereof. In one example embodiment, the photoresist film may contain an organometallic oxide comprising tin oxide (SnO). It is recognized, however, that the photoresist film disclosed herein is not strictly limited to organometallic oxides, and may include other organic and inorganic photoresist film layers suitable for EUV lithography.

The topcoat film may also include a wide variety of organic and inorganic materials. In some embodiments, the topcoat may include a metal oxide or an organometallic oxide having a central metal atom of titanium (Ti). For example, the topcoat film may be titanium oxide (TiO) or an organometallic oxide comprising TiO. However, the topcoat film is not strictly limited to such examples and may include other organic and inorganic topcoat materials. Additional examples of suitable topcoat materials include, but are not limited to, titanium nitride (TiN), titanium oxynitride (TiON), hafnium oxide (HfO), zirconium oxide (ZrO), silicon oxide (SiO), silicon nitride (SiN), silicon oxynitride (SiON), amorphous carbon (a-C), tin oxide (SnOx) and aluminum oxide (Al₂O₃).

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIG. 1 is a flowchart diagram illustrating one embodiment of a method of forming an extreme ultra-violet (EUV) photoresist pattern on a semiconductor substrate in accordance with the present disclosure.

FIGS. 2A-2B illustrate an example process flow that uses the method shown in FIG. 1 to form an EUV photoresist pattern on a semiconductor substrate in accordance with a first embodiment of the present disclosure.

FIG. 3 is a graph illustrating the effect of ultra-violet (UV) treatment in air (UVTA) on inhibition layer adsorption.

FIGS. 4A-4B illustrate an example process flow that utilizes the method shown in FIG. 1 to form an EUV photoresist pattern on a semiconductor substrate in accordance with a second embodiment of the present disclosure.

FIG. 5 illustrates an example process flow that utilizes the method shown in FIG. 1 to form an EUV photoresist pattern on a semiconductor substrate in accordance with a third embodiment of the present disclosure.

FIGS. 6A-6B illustrate an example process flow that utilizes the method shown in FIG. 1 to form an EUV photoresist pattern on a semiconductor substrate in accordance with a fourth embodiment of the present disclosure.

FIG. 7 is a flowchart diagram illustrating another embodiment of a method of forming an EUV photoresist pattern on a semiconductor substrate in accordance with the present disclosure.

FIG. 8 (Prior Art) illustrates a process flow that attempts to deposit a material on a photoresist pattern using area selective deposition (ASD).

### DETAILED DESCRIPTION

The present disclosure provides improved processes and methods of forming a photoresist pattern on a semiconductor substrate. More specifically, the present disclosure provides various embodiments of improved processes and methods that utilize a combination of extreme ultra-violet (EUV) lithography and area selective deposition (ASD) processes to form an EUV photoresist pattern on at least one underlayer formed above a semiconductor substrate.

In the disclosed embodiments, a photoresist film is deposited on at least one underlayer and patterned using EUV lithography to form an EUV photoresist pattern on the underlayer(s). The photoresist film deposited on the underlayer(s) is a relatively thin film having, for example, a thickness less than 15 nm. After the photoresist film is deposited and patterned, an ASD process is used to selectively deposit a topcoat film on the EUV photoresist pattern without depositing the topcoat film on exposed surfaces of the underlayer(s) not covered by the EUV photoresist pattern. The topcoat film may also be a relatively thin film having a thickness less than 10 nm. By selectively depositing the topcoat film on the EUV photoresist pattern, the topcoat film increases the aspect ratio and overall thickness of the EUV photoresist pattern initially formed on the underlayer(s).

A wide variety of ASD processes are used in the embodiments disclosed herein to selectively deposit the topcoat film on the EUV photoresist pattern. In each of the embodiments disclosed herein, an inhibition layer is provided on, or within, the underlayer(s) to enable area selective deposition of the topcoat film on the EUV photoresist pattern. The inhibition layer can be provided on, or within, the underlayer(s) before, during or after EUV lithography is used to create the EUV photoresist pattern. When ASD is used to selectively deposit the topcoat film on the EUV photoresist pattern, the inhibition layer reduces (or substantially prevents) the topcoat film from being deposited on exposed surfaces of the underlayer(s). In some embodiments, the inhibition layer may prevent deposition on the underlayer(s) by providing a hydrophobic surface, which reduces (or substantially prevents) adsorption of the topcoat film on the exposed surfaces of the underlayer(s).

The processes and methods disclosed herein overcome the challenges typically faced when conventional EUV lithography or conventional ASD processes are used to form a photoresist pattern on a semiconductor substrate. As described in more detail below, the processes and methods disclosed herein avoid the photoresist damage and photoresist line or pillar collapse that often occurs during conventional EUV lithography processes, and eliminate pitch dependency problems in conventional ASD processes by utilizing a plurality of photoresist films and a combination of EUV lithography and ASD techniques to create an EUV photoresist pattern on the underlayer(s).

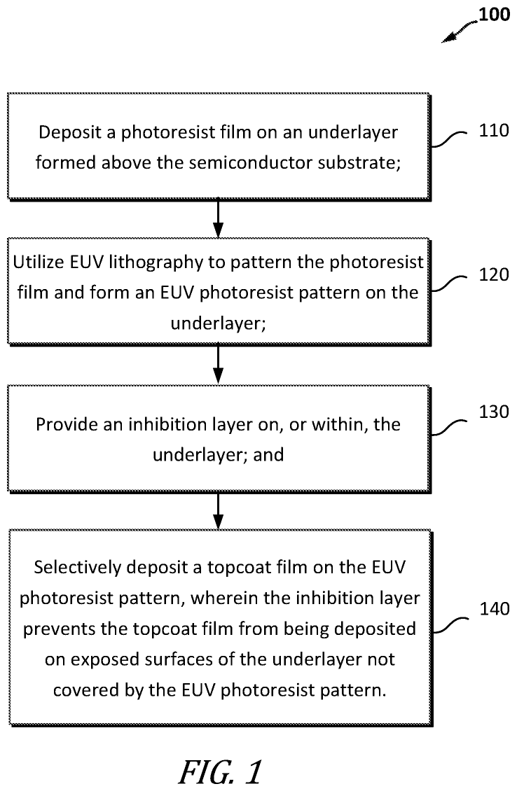

Turning now to the Drawings, FIG. 1 illustrates one embodiment of a method that utilizes the techniques disclosed herein to form a photoresist pattern on a semiconductor substrate. More specifically, FIG. 1 illustrates an exemplary method 100 of forming an EUV photoresist pattern on a semiconductor substrate. It will be recognized that the embodiment of the method 100 shown in FIG. 1 is merely exemplary and additional methods may utilize the techniques described herein. Further, additional processing steps may be added to the method 100 shown in FIG. 1 as the steps described are not intended to be exclusive. Moreover, the order of the steps is not limited to the order shown in the figure as different orders may occur and/or various steps may be performed in combination or at the same time.

The method 100 shown in FIG. 1 includes depositing a photoresist film on an underlayer formed above the semiconductor substrate (in step 110) and utilizing EUV lithography to pattern the photoresist film and form an EUV photoresist pattern on the underlayer (in step 120). The method 100 further includes providing an inhibition layer on, or within, the underlayer (in step 130) and selectively depositing a topcoat film on the EUV photoresist pattern (in step 140). In the method 100 shown in FIG. 1, the inhibition layer provided on, or within, the underlayer (in step 130) prevents the topcoat film from being deposited on exposed surfaces of the underlayer not covered by the EUV photoresist pattern (in step 140).

A wide variety of semiconductor materials may be used to implement the substrate, the underlayer, the inhibition layer, the photoresist film and the topcoat film in the method 100 shown in FIG. 1. Examples of suitable semiconductor materials are provided below for explanatory purposes. However, one skilled in the art having the benefit of this disclosure would readily understand how other semiconductor materials not specifically mentioned herein may also be utilized.

The semiconductor substrate may be any substrate for which patterning of the substrate is desirable. For example, the substrate may be a semiconductor substrate having one or more semiconductor processing layers (all of which together may comprise the substrate) formed thereon. Thus, in one embodiment, the substrate may be a semiconductor substrate that has been subject to multiple semiconductor processing steps which yield a wide variety of structures and layers, all of which are known in the substrate processing art, and which may be considered to be part of the substrate. For example, in one embodiment, the substrate may be a semiconductor wafer having one or more semiconductor processing layers formed thereon. The concepts disclosed herein may be utilized at any stage of the substrate process flow such as, for example, any of the numerous deposition, photolithography and etching steps that may be utilized to form a completed substrate.

The underlayer(s) formed on and/or above the semiconductor substrate may include one or more underlayers commonly used for patterning. Examples of underlayer(s) include, but are not limited to, bottom anti-reflective coating (BARC) layers, hardmask layers, carbon layers and other organic and inorganic material layers. For example, the underlayer(s) may include a carbon (C) layer, an amorphous carbon layer (a-C), a silicon carbide (SiC) layer, a silicon oxycarbide (SiOC) layer, a silicon carbide (SiC) layer, an amorphous silicon layer, a silicon dioxide (SiO₂) layer and/or combinations thereof. Other semiconductor materials suitable for use as underlayers may also be utilized, as discussed further herein and known in the art.

In some embodiments, the underlayer upon which the photoresist film is deposited (in step 110) may include a hydrophilic material or another material that provides good adhesion between the underlayer and the photoresist film. As used herein, a hydrophilic material is defined as a material having a water contact angle less than or equal to 60°. Examples of hydrophilic materials suitable for use as an underlayer include, but are not limited to, amorphous carbon (a-C), silicon oxycarbide (SiOC), amorphous silicon, silicon dioxide (SiO₂) and other metal containing materials having properties that provide good adhesion and allow inhibition molecules to attach to the underlayer.

In other embodiments, the underlayer upon which the photoresist film is deposited (in step 110) may include a hydrophobic material having a water contact angle that is greater than or equal to 90°. Examples of hydrophobic materials suitable for use as an underlayer include, but are not limited to, carbon (C) and silicon carbide (SiC).

The photoresist film deposited in step 110 may include a wide variety of organic and inorganic photoresist film layers. In some embodiments, the photoresist film may be a metal-oxide photoresist film containing an organometallic oxide. In one example, the photoresist film may be an organometallic oxide comprising tin oxide (SnO). It is noted, however, that the photoresist film disclosed herein is not limited to such an example and may include other organometallic oxides having a central metal atom of tin (Sn), zirconium (Zr), indium (In), antimony (Sb), bismuth (Bi), zinc (Zn), hafnium (Hf), aluminum (Al) or combinations thereof. It is further noted that the photoresist film disclosed herein is not strictly limited to organometallic oxides, and may include other organic and inorganic photoresist film layers that are suitable for EUV lithography.

The topcoat film selectively deposited in step 140 may also include a wide variety of organic and inorganic materials. In some embodiments, the topcoat film may be a metal oxide or an organometallic oxide containing a central metal atom of titanium. For example, the topcoat film may be titanium oxide (TiO) or an organometallic oxide comprising TiO. However, the topcoat film is not strictly limited to such examples and may include other organic and inorganic topcoat materials. Additional examples of suitable topcoat materials include, but are not limited to, titanium nitride (TiN), titanium oxynitride (TiON), hafnium oxide (HfO), zirconium oxide (ZrO), silicon oxide (SiO), silicon nitride (SiN), silicon oxynitride (SiON), amorphous carbon (a-C), tin oxide (SnOx) and aluminum oxide (Al₂O₃).

In some embodiments, the inhibition layer provided in step 130 may reduce (or prevent) deposition of the topcoat film on the exposed surfaces of the underlayer (in step 140) by reducing (or preventing) adsorption of the topcoat film on the exposed surfaces of the underlayer. For example, the inhibition layer may include a hydrophobic material (for example, a material having a water contact angle greater than or equal to) 90° to reduce or prevent the topcoat film from adsorbing onto the exposed surfaces of the underlayer. Examples of hydrophobic materials suitable for use as an inhibition layer include, but are not limited to, materials having relatively small molecules (e.g., short chain molecules having less than 2-3 carbon chains), materials having methyl end groups (e.g., trimethylsilyl (Si(CH₃)₃) end groups), benzene end groups or fluorocarbon end groups and self-assembled monolayers (SAMs) having head groups tailored to the underlayer materials, such as but not limited to, silane, carboxylic or phosphonic head groups. Examples of hydrophobic materials suitable for use as an inhibition layer are described in more detail below.

A wide variety of deposition processes can be used to form the material layers shown and described herein. For example, the underlayer, the inhibition layer, the photoresist film and the topcoat film may be deposited using one or more deposition techniques including, but not limited to, spin-on deposition, chemical vapor deposition (CVD), plasma enhanced CVD (PECVD), physical vapor deposition (PVD), atomic layer deposition (ALD), and/or other deposition processes.

A variety of wet and dry deposition techniques may also be used to form the underlayer(s) on and/or above the semiconductor substrate. In some embodiments, a spin-on deposition process may be used to deposit a hydrophilic underlayer (such as, for example, an amorphous carbon (a-C), silicon oxycarbide (SiOC), amorphous silicon or silicon dioxide (SiO₂) layer) above the semiconductor substrate using a variety of liquids, liquid flow rates and spin chuck rotational speeds. In other embodiments, a vapor phase deposition process (such as PECVD) may be used to deposit a hydrophobic underlayer (for example, a carbon (C) or silicon carbide (SiC) layer) above the substrate using a variety of gas chemistries at a variety of pressure, power, gas flow rate and temperature conditions.

In some embodiments, the photoresist film may be deposited using various dry deposition techniques. For example, the photoresist film may be deposited using chemical vapor deposition (CVD), chemical vapor polymerization (CVP) or atomic layer deposition (ALD). U.S. patent application Ser. No. 18/216,168, which is entitled “Methods of Forming Photosensitive Organometallic Oxides by Chemical Vapor Polymerization,” filed Jun. 29, 2023, and incorporated herein in its entirety, discloses one example of a CVP process that can be used to deposit the photoresist film disclosed herein. The topcoat film may be deposited using chemical vapor deposition (CVD), atomic layer deposition (ALD) or molecular layer deposition (MLD) processes. In some embodiments, the topcoat film may be selectively deposited using spatial ALD or sub-saturation ALD to provide additional selectivity, or increase the deposition thickness of the topcoat film, on the top of the EUV photoresist pattern.

The deposition techniques used to deposit the photoresist film and the topcoat film may utilize a variety of gas chemistries at a variety of pressure, power, gas flow rate and temperature conditions. Other operating variables can also be adjusted to control the various deposition processes described herein. The operating variables may include, for example, the chamber temperature, chamber pressure, flowrates of liquids and/or gases, types of liquids and/or gases, and/or other operating variables for the processing steps. Variations can also be implemented while still taking advantage of the techniques described herein.

The method 100 shown in FIG. 1 utilizes a combination of EUV lithography and ASD techniques to form an EUV photoresist pattern on at least one underlayer formed above a semiconductor substrate. After the photoresist film is deposited and patterned using EUV lithography to form the EUV photoresist pattern on the underlayer(s), an ASD technique is utilized to selectively deposit the topcoat film on the EUV photoresist pattern. The selective deposition of the topcoat film increases the aspect ratio and overall thickness of the EUV photoresist pattern initially formed on the underlayer(s), while the inhibition layer avoids depositing the topcoat film on the exposed surfaces of the underlayer(s).

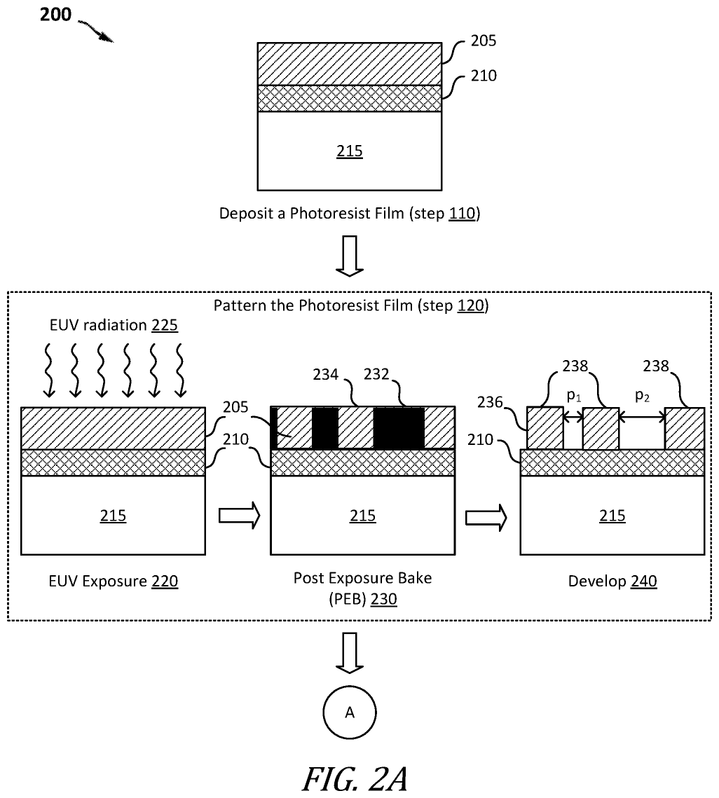

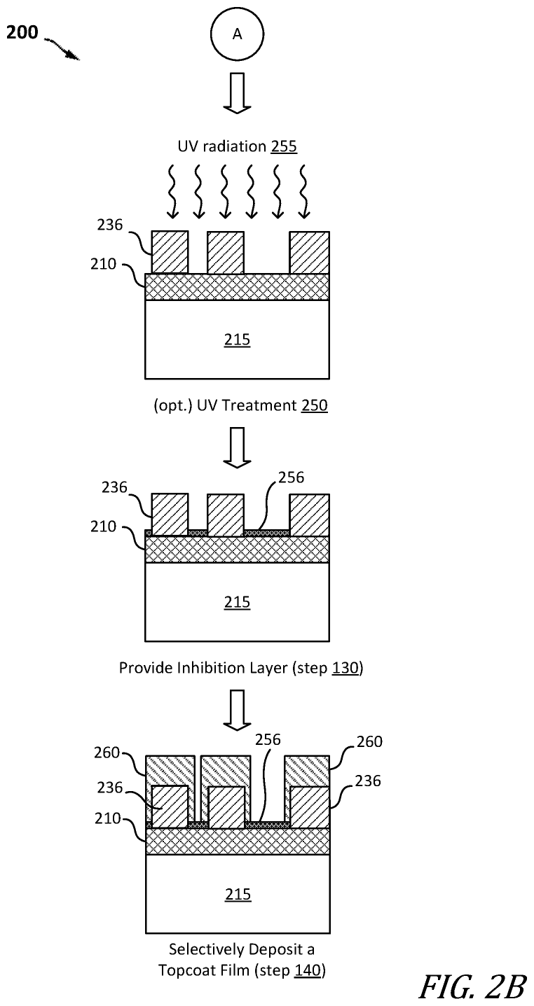

A wide variety of ASD techniques can be used in step 140 to selectively deposit the topcoat film on the EUV photoresist pattern. Example process flows are provided in FIGS. 2A-2B, FIGS. 4A-4B, FIG. 5 and FIGS. 6A-6B for forming an EUV photoresist pattern on a semiconductor substrate. In each of the process flows discussed below, a different ASD technique is used to selectively deposit the topcoat film on the EUV photoresist pattern.

FIGS. 2A-2B illustrate an example process flow 200 that uses the method 100 shown in FIG. 1 to form an EUV photoresist pattern on a semiconductor substrate in accordance with a first embodiment of the present disclosure. Like the method 100 described above, the process flow 200 begins by depositing a photoresist film 205 on at least one underlayer 210 formed above a semiconductor substrate 215 (in step 110). The photoresist film 205, the underlayer 210 and the semiconductor substrate 215 may comprise a variety of materials as described in more detail above. For example, the photoresist film 205 may be a metal-oxide photoresist containing an organometallic oxide (for example, an organometallic oxide comprising tin oxide) and the underlayer 210 may comprise a hydrophilic material (for example, a material having a water contact angle less than or equal to) 60° that provides good adhesion between the underlayer 210 and the photoresist film 205.

After depositing the photoresist film 205 (in step 110), the process flow 200 uses EUV lithography to pattern the photoresist film 205 and form an EUV photoresist pattern 236 on the underlayer 210 (in step 120). As shown in FIG. 2A, the EUV lithography process exposes the semiconductor substrate 215 containing the photoresist film 205 to EUV radiation 225 (for example, at a wavelength of 13.5 nm) in an EUV exposure step 220. The EUV lithography process may utilize a photomask (not shown) such that a photo-induced reaction occurs only in regions 232 of the photoresist film 205 exposed to the EUV radiation 225. The regions 232 of the photoresist film 205 exposed to the EUV radiation 225 are converted to a reacted photoresist. Regions 234 of the photoresist film 205 not exposed to the EUV radiation 225 remain unreacted. After the EUV exposure step 220, an optional post-exposure bake (PEB) step 230 (or other heat-treating step) may be performed to stabilize the photoresist after EUV exposure by completing the reactions initiated during exposure. In some embodiments, the optional heat-treating step may prevent changes in line edge roughness (LER), line width roughness (LWR) and/or critical dimension (CD).

After completing the EUV exposure step 220 and the optional post-exposure bake (PEB) step 230, a developing step 240 is performed to remove a portion of the photoresist film 205 for patterning, thereby providing an EUV photoresist pattern 236 on the underlayer 210. The developing step 240 may be a wet or dry process. For example, a portion of the photoresist film 205 may be removed by treating the substrate with a developing solution to dissolve the reacted regions 232 (in case of a positive tone resist) or unreacted regions 234 (in case of a negative tone resist) of the photoresist film 205. Alternately, a dry process may be used to remove the reacted or unreacted regions of the photoresist film 205. The dry process may comprise, for example, a selective plasma etch process or a thermal process, advantageously eliminating the use of a developing solution. In certain embodiments, the dry process may be performed using reactive ion etching (RIE) process or atomic layer etching (ALE).

After the developing step 240, the EUV photoresist pattern 236 formed on the underlayer 210 includes a plurality of photoresist structures 238. In some embodiments, the pitch (p) between the plurality of photoresist structures 238 may vary. As shown in FIG. 2A, for example, some of the photoresist structures 238 may have smaller pitch (p₁), whereas other photoresist structures 238 have comparatively larger pitch (p₂) between structures.

After the photoresist film 205 is deposited and patterned to form the EUV photoresist pattern 236 as shown in FIG. 2A, the process flow 200 uses area selective deposition to selectively deposit the topcoat film 260 on the EUV photoresist pattern 236 without depositing the topcoat film 260 on exposed surfaces of the underlayer 210, as shown in FIG. 2B. To enable area selective deposition, an inhibition layer 256 is provided on the exposed surfaces of the underlayer 210 (in step 130) in FIG. 2B after the EUV photoresist pattern 236 is formed in FIG. 2A.

A wide variety of underlayer 210 materials may be utilized in the process flow 200 shown in FIGS. 2A-2B. For example, the underlayer 210 shown in FIG. 2A may generally include a hydrophilic material or another material that provides good adhesion between the underlayer 210 and the photoresist film 205. Examples of hydrophilic materials suitable for use as an underlayer 210 in the process flow 200 include, but are not limited to, amorphous carbon (a-C), silicon oxycarbide (SiOC), amorphous silicon, silicon dioxide (SiO₂) and other metal containing materials having properties that provide good adhesion and allow inhibition molecules to attach to the underlayer.

The inhibition layer 256 shown in FIG. 2B may include a wide variety of hydrophobic materials (for example, materials having a water contact angle greater than or equal to) 90°. Examples of hydrophobic materials suitable for use as the inhibition layer 256 include, but are not limited to, materials having relatively small molecules (e.g., short chain molecules having less than 2-3 carbon chains), materials having methyl end groups (e.g., trimethylsilyl (Si(CH₃)₃) end groups), benzene end groups or fluorocarbon end groups and self-assembled monolayers (SAMs) having head groups tailored to the underlayer materials, such as but not limited to, silane, carboxylic or phosphonic head groups. Non-limiting examples of suitable SAMs include octadecyltrichlorosilane (ODTS), dodecyl thiol (DDT), octadecylphosphonic acid (ODPA). In some embodiments, the inhibition layer 256 may include silane groups such as, but not limited to, trimethylsilane dimethylamine (TMSDMA) and octadecyltrichlorosilane (ODTS).

In some embodiments, the inhibition layer 256 may be selectively deposited on the exposed surfaces of the underlayer 210 by exposing the semiconductor substrate 215 to an optional ultra-violet (UV) treatment (in step 250). When utilized, the optional UV treatment step 250 may enable selective adsorption of the inhibition layer 256 on the exposed surfaces of the underlayer 210, rather than on the EUV photoresist pattern 236. In some embodiments, the optional UV treatment step 250 may expose the semiconductor substrate 215 to UV radiation 255 in the presence of an oxidizing species (for example, air, ozone or another oxidizing species containing oxygen radicals) to form hydroxide groups (not shown in FIG. 2B) on the exposed surfaces of the underlayer 210. The inhibition layer 256 may then react with the hydroxide groups to selectively adsorb onto the exposed surfaces of the underlayer 210.

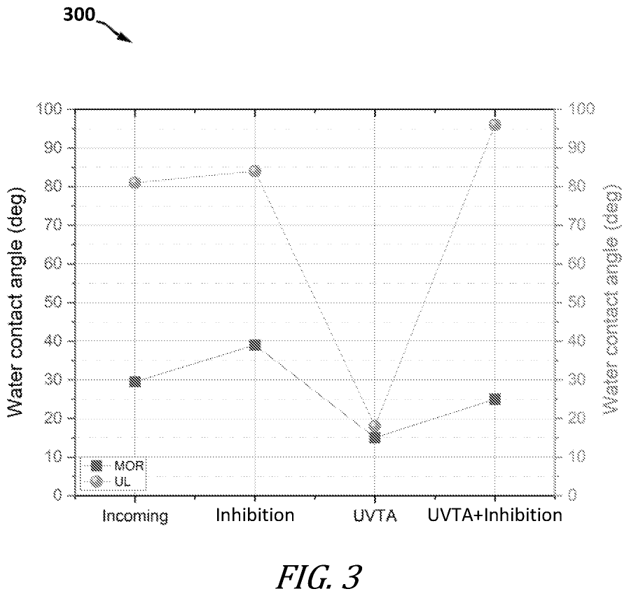

A graph 300 is provided in FIG. 3 to illustrate the effect of UV treatment in air (UVTA) on inhibition layer adsorption. As shown in the graph 300, the incoming EUV photoresist pattern 236 (metal-oxide resist, MOR) and the incoming underlayer 210 (UL) have a water contact angle of approximately 30° and 80°, respectively, prior to UV treatment (in step 250) and inhibition layer 256 deposition (in step 130). Depositing the inhibition layer 256 without UV treatment does not significantly affect the water contact angle of the EUV photoresist pattern 236 (MOR) or the underlayer 210 (UL). This proves that the inhibition layer 256 does not adhere to the EUV photoresist pattern 236 (MOR) or the underlayer 210 (UL) without UV treatment.

As shown in the graph 300, the EUV photoresist pattern 236 (MOR) and the underlayer 210 (UL) are both hydrophilic and have a water contact angle less than 30° when exposed to UV radiation 255 in air (or another oxidizing species). After UV treatment (in step 250) and inhibition layer 256 deposition (in step 130), the EUV photoresist pattern 236 (MOR) remains hydrophilic, while the underlayer 210 becomes hydrophobic (having a water contact angle greater than) 90°. This proves that the inhibition layer 256 is selectively deposited on the underlayer 210 (UL), rather than the EUV photoresist pattern 236 (MOR). By exposing the semiconductor substrate 215 to UV radiation 255 in the presence of an oxidizing species (such as air) to form hydroxide groups on the exposed surfaces of the underlayer 210, the optional UV treatment step 250 shown in FIGS. 2B and 3 enables selective adsorption of the inhibition layer 256 on the exposed surfaces of the underlayer 210, while substantially preventing adsorption of the inhibition layer 256 on the EUV photoresist pattern 236. Although not strictly limited to such theory, the selective adsorption of the inhibition layer 256 on the exposed surfaces of the underlayer 210 is most likely due to the fact that silane groups react better with hydroxide groups than metal-oxides.

After providing the inhibition layer 256 on the exposed surfaces of the underlayer 210 (in step 130), the process flow 200 selectively deposits the topcoat film 260 on the EUV photoresist pattern 236 (in step 140) to increase the aspect ratio and overall thickness of the EUV photoresist pattern 236 initially formed on the underlayer 210. By providing a hydrophobic surface during the selective deposition process, the inhibition layer 256 provided on the underlayer 210 prevents the topcoat film 260 from being deposited on the exposed surfaces of the underlayer 210 (in step 140), as shown in FIG. 2B.

In the process flow 200 shown in FIGS. 2A-2B, the underlayer 210 contains a hydrophilic material and the inhibition layer 256 contains a hydrophobic material (such as TMSDMA or another silane), which reduces or substantially prevents the topcoat film 260 from being deposited on the exposed surfaces of the underlayer 210 (in step 140) between the photoresist structures 238. In the embodiment shown in FIGS. 2A-2B, the inhibition layer 256 is provided on the underlayer 210 (in step 130) after EUV lithography is used to form the EUV photoresist pattern 236 (in step 120). In other embodiments, however, the inhibition layer 256 may be provided within the underlayer 210 (in step 130) before, during or after EUV lithography is used to form the EUV photoresist pattern 236 (in step 120).

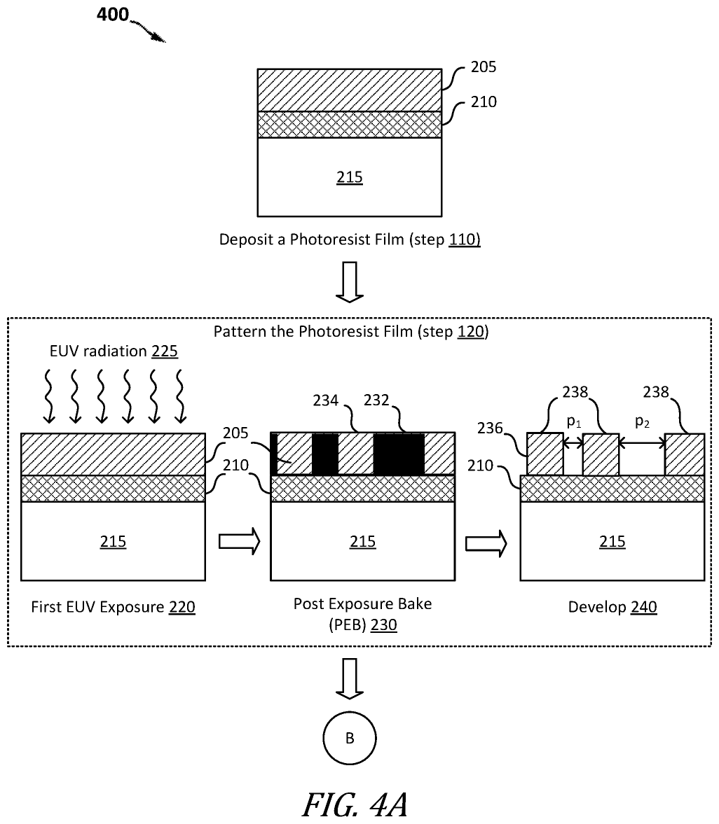

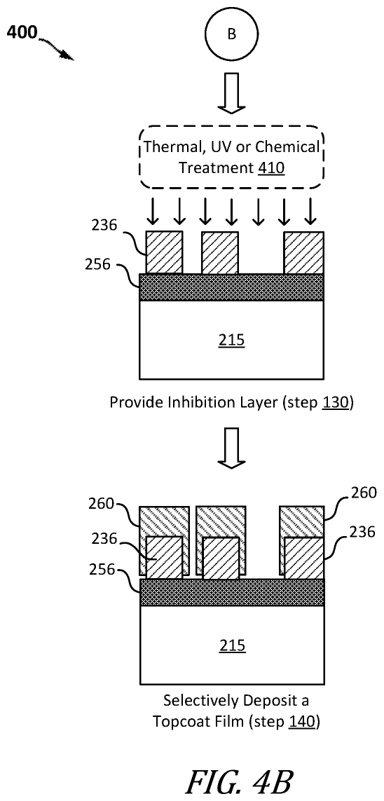

FIGS. 4A-4B illustrate an example process flow 400 that utilizes the method 100 shown in FIG. 1 to form an EUV photoresist pattern on a semiconductor substrate in accordance with a second embodiment of the present disclosure. The process flow 400 steps shown in FIG. 4A are identical to the process flow 200 steps shown in FIG. 2A, and thus, will not be repeated herein for the purpose of brevity.

After the photoresist film 205 is deposited and patterned to form the EUV photoresist pattern 236 as shown in FIG. 4A, the process flow 400 uses another area selection deposition technique to selectively deposit the topcoat film 260 on the EUV photoresist pattern 236 without depositing the topcoat film 260 on exposed surfaces of the underlayer 210. In the embodiment shown in FIG. 4B, the inhibition layer 256 is provided within the underlayer 210 (in step 130) by converting the underlayer 210 into the inhibition layer 256 after the photoresist film 205 is deposited and patterned to form the EUV photoresist pattern 236 (in step 120).

In some embodiments, the process flow 400 may convert the underlayer 210 into the inhibition layer 256 by exposing the semiconductor substrate 215 to a thermal, UV or chemical treatment 410, which converts at least the exposed surfaces of the underlayer 210 from a hydrophilic to a hydrophobic surface, as shown in FIG. 4B. A wide variety of underlayer 210 materials may be utilized in the process flow 400 shown in FIGS. 4A-4B. For example, the underlayer 210 shown in FIG. 4A may include a silicon oxycarbonitride layer having a chemical formula of Si_{X}O_{Y}C_{Z}Nₐ, where 0≤x≤1, 0≤y≤1, 0≤z≤1 and 0≤a≤1.

In some embodiments, the semiconductor substrate 215 may be exposed to a thermal treatment in FIG. 4B to convert at least the exposed surfaces of the underlayer 210 from a hydrophilic to a hydrophobic surface. The thermal treatment may expose the semiconductor substrate 215 to an elevated temperature, which is high enough to convert the exposed surfaces of the underlayer 210 to a hydrophobic surface without causing thermal decomposition of photoresist film 205. In one example, the substrate temperature or the surrounding ambient temperature may be greater than approximately 200° C.

In other embodiments, the semiconductor substrate 215 may be exposed to a UV treatment in FIG. 4B to convert at least the exposed surfaces of the underlayer 210 from a hydrophilic to a hydrophobic surface. The UV treatment may expose the semiconductor substrate 215 to UV radiation in the presence of oxygen (O₂), nitrogen (N₂) and/or argon (Ar) to convert the exposed surfaces of the underlayer 210 to a hydrophobic surface.

In yet other embodiments, the semiconductor substrate 215 may be exposed to a chemical treatment in FIG. 4B to convert at least the exposed surfaces of the underlayer 210 from a hydrophilic to a hydrophobic surface. For example, the chemical treatment may expose the semiconductor substrate 215 to ozonated water to convert the exposed surfaces of the underlayer 210 to a hydrophobic surface.

After utilizing a thermal, UV or chemical treatment 410 to convert the underlayer 210 into the inhibition layer 256, the process flow 400 selectively deposits the topcoat film 260 on the EUV photoresist pattern 236 (in step 140) to increase the aspect ratio and overall thickness of the EUV photoresist pattern 236 initially formed on the underlayer 210. By providing a hydrophobic surface during the selective deposition process, the inhibition layer 256 provided within the underlayer 210 (in step 130) prevents the topcoat film 260 from being deposited on the exposed surfaces of the underlayer 210 (in step 140).

In the process flow 400 shown in FIGS. 4A-4B, the underlayer 210 formed above the semiconductor substrate 215 includes a hydrophilic material, which is converted into a hydrophobic inhibition layer 256 after the EUV photoresist pattern 236 is formed. By converting exposed surfaces of the underlayer 210 from a hydrophilic to a hydrophobic surface, the process flow 400 reduces or substantially prevents the topcoat film 260 from being deposited on the exposed surfaces of the underlayer 210 (in step 140) between the photoresist structures 238.

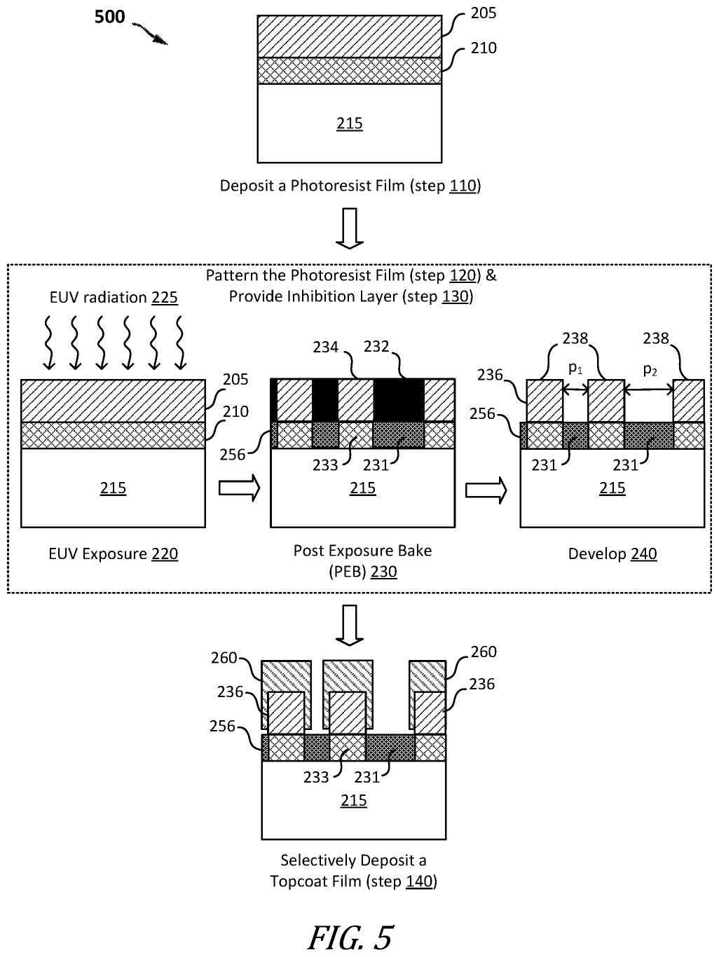

FIG. 5 illustrates an example process flow 500 that utilizes the method 100 shown in FIG. 1 to form an EUV photoresist pattern 236 on a semiconductor substrate 215 in accordance with a third embodiment of the present disclosure. Like the previous embodiments shown in FIGS. 2A-2B and FIGS. 4A-4B, the process flow 500 deposits a photoresist film 205 on at least one underlayer 210 formed above the semiconductor substrate 215 (in step 110) before using EUV lithography to pattern the photoresist film 205 and form an EUV photoresist pattern on the underlayer 210 (in step 120). A wide variety of underlayer 210 materials may be utilized in the process flow 500 shown in FIG. 5. For example, the underlayer 210 shown in FIG. 5 may include a silicon oxycarbonitride layer having a chemical formula of Si_{X}O_{Y}C_{Z}Nₐ, where 0≤x≤1, 0≤y≤1, 0≤z≤1 and 0≤a≤1. In some embodiments, inert gases such as nitrogen (N₂) or argon (Ar) used during the EUV exposure may induce additional surface modification.

In the process flow 500 shown in FIG. 5, the inhibition layer 256 is provided within the underlayer 210 (in step 130) during the EUV lithography process used to form the EUV photoresist pattern 236. When the semiconductor substrate 215 is exposed to EUV radiation 225 in the EUV exposure step 220, the regions 232 of the photoresist film 205 exposed to EUV radiation 225 (i.e., the regions not covered by the photomask) are converted to a reacted photoresist, while the regions 234 of the photoresist film 205 not exposed to the EUV radiation 225 remain unreacted. In addition converting select portions of the photoresist film 205 to a reacted photoresist, the EUV radiation 225 shown in FIG. 5 converts at least a portion of the underlayer 210 from a hydrophilic to a hydrophobic material.

For example, the EUV radiation 225 shown in FIG. 5 may convert the portions 231 of the underlayer 210 underlying the regions 232 of the photoresist film 205 (i.e., the reacted photoresist) into a hydrophobic material, while the portions 233 of the underlayer 210 underlying the regions 234 of the photoresist film 205 (i.e., the unreacted photoresist) remain hydrophilic. In some embodiments, the EUV radiation 225 applied to the substrate may convert an entire thickness of the portions 231 into a hydrophobic material, as shown in FIG. 5. In other embodiments, the EUV radiation 225 may convert less than the entire thickness of the portions 231 into a hydrophobic material. After the developing step 140 is performed to remove the reacted regions 232 of the photoresist film 205 and form the EUV photoresist pattern 236, the converted portions 231 of the underlayer 210 provide a hydrophobic surface, which repels the topcoat film 260 during the subsequent deposition process.

After EUV lithography is performed to form the EUV photoresist pattern 236 (in step 120) and provide the inhibition layer 256 within the underlayer 210 (in step 130), the process flow 500 selectively deposits the topcoat film 260 on the EUV photoresist pattern 236 (in step 140) to increase the aspect ratio and overall thickness of the EUV photoresist pattern 236 initially formed on the underlayer 210. By providing a hydrophobic surface during the selective deposition process, the inhibition layer 256 provided within the underlayer 210 prevents the topcoat film 260 from being deposited on the exposed surfaces of the underlayer 210 (in step 140).

In the process flow 500 shown in FIG. 5, the underlayer 210 formed above the semiconductor substrate 215 includes a hydrophilic material, which is converted into a hydrophobic inhibition layer 256 during the EUV lithography process as the EUV photoresist pattern 236 is being formed. By converting the portions 231 of the underlayer 210 from a hydrophilic to a hydrophobic material, the process flow 500 reduces or substantially prevents the topcoat film 260 from being deposited on the exposed surfaces of the underlayer 210 (in step 140) between the photoresist structures 238.

In the process flows shown in FIGS. 2A-2B, FIGS. 4A-4B and FIG. 5, the underlayer 210 formed above the semiconductor substrate 215 includes a hydrophilic material, which provides good adhesion between the underlayer 210 and the photoresist film 205 deposited thereon. However, the underlayer 210 described herein is not strictly limited to hydrophilic materials. In other embodiments, the underlayer 210 formed above the semiconductor substrate 215 may include a hydrophobic material, rather than a hydrophilic material. When a hydrophobic underlayer is utilized, a sacrificial hydrophilic layer is deposited on the underlayer 210 before depositing the photoresist film 205.

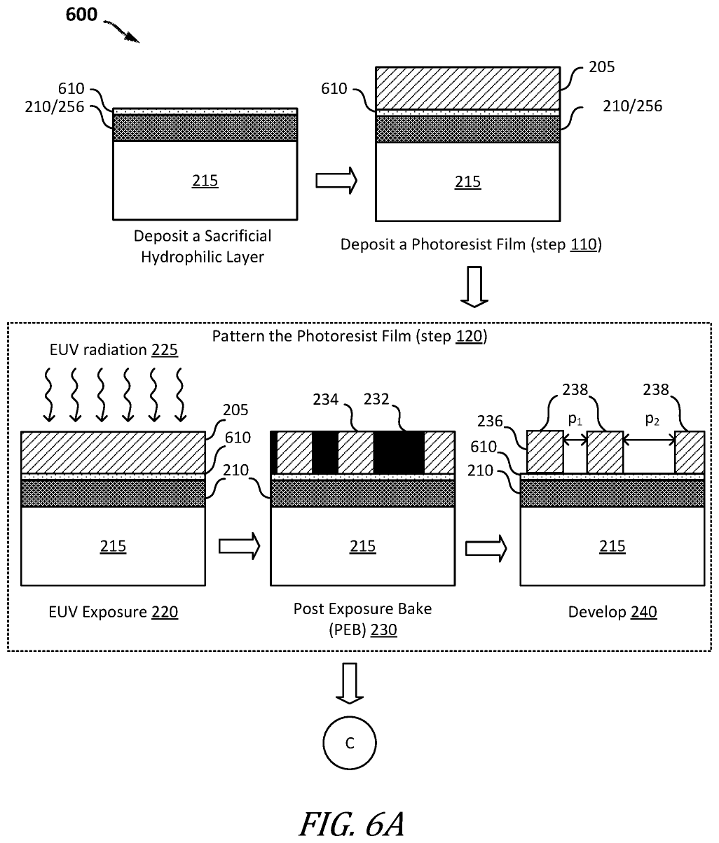

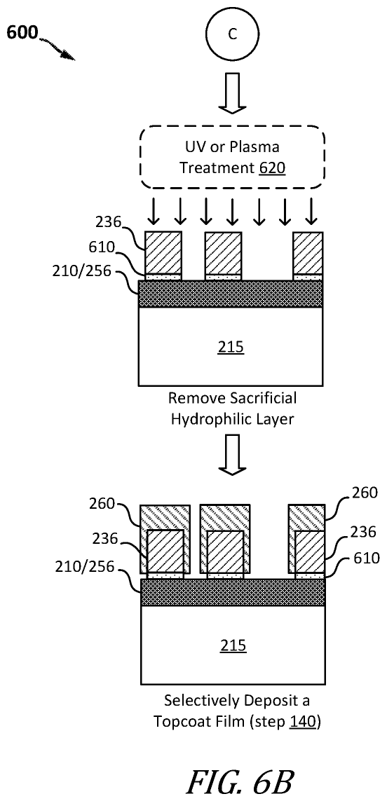

FIGS. 6A-6B illustrate an example process flow 600 that utilizes the method 100 shown in FIG. 1 to form an EUV photoresist pattern 236 on a semiconductor substrate 215 in accordance with a fourth embodiment of the present disclosure. Unlike the previous embodiments, the process flow 600 begins by depositing a sacrificial hydrophilic layer 610 (having a water contact angle less than or equal to) 60° on a hydrophobic underlayer 210 prior to depositing the photoresist film 205 (in step 110). Because the underlayer 210 contains a hydrophobic material, the sacrificial hydrophilic layer 610 is needed to provide good adhesion for the photoresist film 205 when the photoresist film 205 is deposited in step 110. A wide variety of hydrophobic underlayer materials and sacrificial hydrophilic materials can be used in the process flow 600 shown in FIG. 6A. For example, the underlayer 210 may include carbon (C) or silicon carbide (SiC), and the sacrificial hydrophilic layer 610 may include amorphous carbon (a-C), silicon oxycarbide (SiOC) or oxomethyl (CxOyHz, where 0≤x≤1, 0≤y≤1 and 0≤z≤1).

After depositing the photoresist film 205 on the sacrificial hydrophilic layer 610, the process flow 600 uses EUV lithography to pattern the photoresist film 205 and form an EUV photoresist pattern on the underlayer 210 (in step 120). The EUV lithography process shown in FIG. 6A includes an EUV exposure step 220, an optional post-exposure bake (PEB) step 230 and a developing step 240, similar to that shown and described above in reference to FIG. 2A.

After forming the EUV photoresist pattern 236 (in step 120), as shown and described in FIGS. 2A and 6A, the process flow 600 uses a UV or plasma treatment 620 to remove portions of the sacrificial hydrophilic layer 610 (not covered by the EUV photoresist pattern 236) and expose the hydrophobic underlayer 210 as shown in FIG. 6B. When the topcoat film 260 is selectively deposited on the EUV photoresist pattern 236 (in step 140), the hydrophobic underlayer 210 acts as the inhibition layer 256 to prevent the topcoat film 260 from being deposited on the exposed surfaces of the underlayer 210 not covered by the EUV photoresist pattern 236.

In the process flow 600 shown in FIGS. 6A-6B, the underlayer 210 formed above the semiconductor substrate 215 includes a hydrophobic material, rather than a hydrophilic material. By depositing a hydrophobic underlayer 210 on the semiconductor substrate 215 before the EUV photoresist pattern 236 is formed on the underlayer 210, the process flow 600 reduces or substantially prevents the topcoat film 260 from being deposited on the exposed surfaces of the underlayer 210 (in step 140) between the photoresist structures 238.

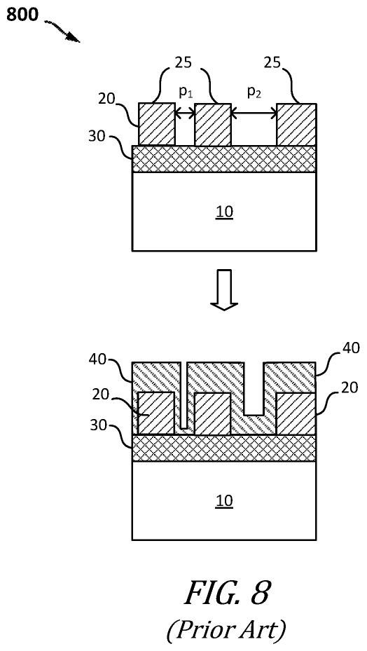

As shown in FIGS. 2A-2B, FIGS. 4A-4B, FIG. 5 and FIGS. 6A-6B, the process flows disclosed herein utilize a combination of EUV lithography and ASD techniques to create an EUV photoresist pattern 236 on at least one underlayer 210 formed above the semiconductor substrate 215. In each of the process flows disclosed herein, an inhibition layer 256 is provided on the underlayer 210 (in the embodiment shown in FIGS. 2A-2B) or within the underlayer 210 (in the embodiments shown in FIGS. 4A-4B, FIG. 5 and FIGS. 6A-6B) to enable area selective deposition of the topcoat film 260 on the EUV photoresist pattern 236, while substantially preventing deposition of the topcoat film 260 on the exposed surfaces of the underlayer 210. In doing so, the process flows disclosed herein avoid the photoresist damage and photoresist line or pillar collapse that often occurs during conventional EUV lithography processes, and eliminate the pitch dependency problems that occur in conventional ASD processes (as shown, for example, in FIG. 8).

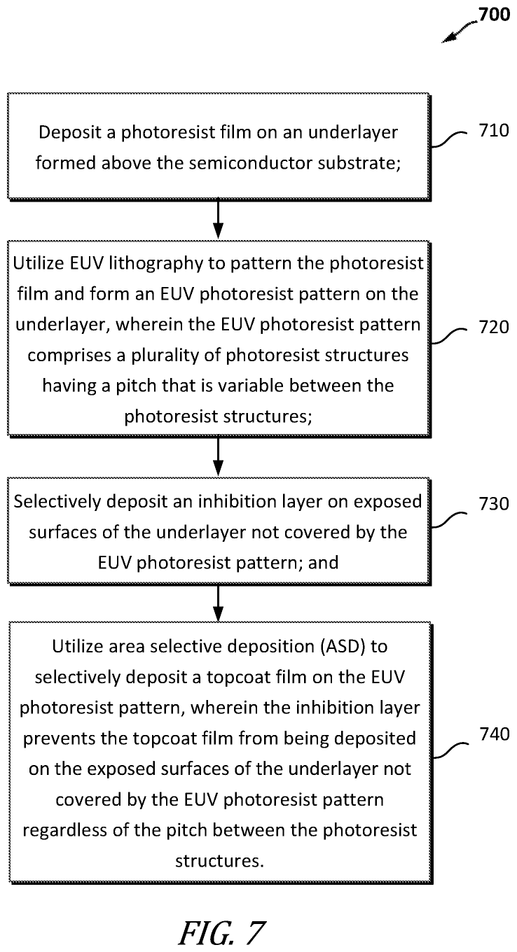

FIG. 7 illustrates another exemplary method 700 of forming an EUV photoresist pattern on a semiconductor substrate in accordance with the present disclosure. It will be recognized that the embodiment of the method 700 shown in FIG. 7 is merely exemplary and additional methods may utilize the techniques described herein. Further, additional processing steps may be added to the method 100 shown in FIG. 7 as the steps described are not intended to be exclusive. Moreover, the order of the steps is not limited to the order shown in the figure as different orders may occur and/or various steps may be performed in combination or at the same time.

Like the previous method 100 shown in FIG. 1, the method 700 shown in FIG. 7 includes depositing a photoresist film on an underlayer formed above the semiconductor substrate (in step 710) and utilizing EUV lithography to pattern the photoresist film and form an EUV photoresist pattern on the underlayer (in step 720). In the method 700, the EUV photoresist pattern formed in step 720 includes a plurality of photoresist structures, wherein the pitch (p) is variable between the photoresist structures. As shown in FIG. 2A, for example, the EUV photoresist pattern formed in step 720 may include a plurality of photoresist structures 238, where some of the photoresist structures 238 have smaller pitch (p₁), while other photoresist structures 238 have comparatively larger pitch (p₂) between the structures.

The method 700 further includes selectively depositing an inhibition layer on exposed surfaces of the underlayer not covered by the EUV photoresist pattern (in step 730), and utilizing area selective deposition (ASD) to selectively deposit a topcoat film on the EUV photoresist pattern (in step 740). In the method 700, the inhibition layer selectively deposited in step 730 prevents the topcoat film from being deposited on the exposed surfaces of the underlayer not covered by the EUV photoresist pattern in step 740, regardless of the pitch (p) between the photoresist structures. FIGS. 2A-2B illustrate one example of a process flow 200 that utilizes the method 700 shown in FIG. 7 to form an EUV photoresist pattern on a semiconductor substrate. It is recognized, however, that other process flows may also use the method 700 to create an EUV photoresist pattern.

The present disclosure provides various embodiments of improved process flows and methods of forming an EUV photoresist pattern on a semiconductor substrate. The disclosed embodiments improve upon conventional process flows and methods of forming EUV photoresists by utilizing a combination of EUV lithography and ASD techniques to create a EUV photoresist pattern on at least one underlayer formed above a semiconductor substrate. By utilizing the techniques described above, the process flows and methods disclosed herein provide an EUV photoresist that does not suffer from photoresist damage, photoresist line or pillar collapse or pitch dependency problems.

The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method of forming an extreme ultra-violet (EUV) photoresist pattern on a semiconductor substrate, the method comprising:
depositing a photoresist film on an underlayer formed above the semiconductor substrate;
utilizing EUV lithography to pattern the photoresist film and form an EUV photoresist pattern on the underlayer;
providing an inhibition layer on, or within, the underlayer; and
selectively depositing a topcoat film on the EUV photoresist pattern, wherein the inhibition layer prevents the topcoat film from being deposited on exposed surfaces of the underlayer not covered by the EUV photoresist pattern.

2. The method of claim 1, wherein the EUV photoresist pattern comprises a plurality of photoresist structures having a pitch that is variable between the photoresist structures, and wherein the inhibition layer prevents the topcoat film from being deposited on the exposed surfaces the underlayer not covered by the EUV photoresist pattern regardless of the pitch between the photoresist structures.

3. The method of claim 1, wherein at least one of the photoresist film and the topcoat film contains an organometallic oxide.

4. The method of claim 3, wherein the organometallic oxide has a central metal atom of tin (Sn), titanium (Ti), zirconium (Zr), indium (In), antimony (Sb), bismuth (Bi), zinc (Zn), hafnium (Hf), aluminum (Al) or combinations thereof.

5. The method of claim 1, wherein the underlayer comprises a hydrophilic material having a water contact angle less than or equal to 60° and the inhibition layer comprises a hydrophobic material having a water contact angle greater than or equal to 90°.

6. The method of claim 5, wherein said providing the inhibition layer comprises:
selectively depositing the inhibition layer on the exposed surfaces of the underlayer after the photoresist film is deposited and patterned to form the EUV photoresist pattern.

7. The method of claim 6, wherein the underlayer comprises amorphous carbon (a-C), silicon oxycarbide (SiOC), amorphous silicon or silicon dioxide (SiO₂), and wherein the inhibition layer comprises materials having short chain molecules, materials having methyl end groups, benzene end groups or fluorocarbon end groups, and self-assembled monolayers (SAMs) having silane head groups, carboxylic head groups or phosphonic head groups.

8. The method of claim 6, wherein before said selectively depositing the inhibition layer, the method comprises:
exposing the semiconductor substrate to an ultra-violet (UV) treatment to enable selective adsorption of the inhibition layer on the exposed surfaces of the underlayer, rather than on the EUV photoresist pattern, during said selectively depositing the inhibition layer.

9. The method of claim 8, wherein said exposing the semiconductor substrate to the ultra-violet (UV) treatment comprises:
exposing the semiconductor substrate to UV radiation in the presence of an oxidizing species to form hydroxide groups on the exposed surfaces of the underlayer; and
wherein the inhibition layer reacts with the hydroxide groups to selectively adsorb on the exposed surfaces of the underlayer.

10. The method of claim 5, wherein said providing the inhibition layer comprises:
converting the underlayer into the inhibition layer after the photoresist film is deposited and patterned to form the EUV photoresist pattern.

11. The method of claim 10, wherein said converting the underlayer into the inhibition layer comprises:
exposing the semiconductor substrate to a thermal, ultra-violet (UV) or chemical treatment to convert at least the exposed surfaces of the underlayer from a hydrophilic surface having a water contact angle less than or equal to 60° to a hydrophobic surface having a water contact angle greater than or equal to 90°.

12. The method of claim 11, wherein the underlayer comprises a silicon oxycarbonitride layer having a chemical formula of Si_{X}O_{Y}C_{Z}Nₐ, where 0≤x≤1, 0≤y≤1, 0≤z≤1 and 0≤a≤1.

13. The method of claim 5, wherein said providing the inhibition layer comprises:
converting the underlayer into the inhibition layer during said utilizing EUV lithography to pattern the photoresist film and form the EUV photoresist pattern on the underlayer.

14. The method of claim 13, wherein said converting the underlayer into the inhibition layer comprises:
exposing the semiconductor substrate to EUV radiation to convert portions of the underlayer from a hydrophilic surface having a water contact angle less than 60° to a hydrophobic surface having a water contact angle greater than 90°.

15. The method of claim 13, wherein the underlayer comprises a silicon oxycarbonitride layer having a chemical formula of Si_{X}O_{Y}C_{Z}Nₐ, where 0≤x≤1, 0≤y≤1, 0≤z≤1 and 0≤a≤1.

16. The method of claim 1, wherein the underlayer comprises a hydrophobic material having a water contact angle greater than or equal to 90°.

17. The method of claim 16, further comprising:
depositing a sacrificial hydrophilic material having a water contact angle less than or equal to 60° on the underlayer prior to said depositing the photoresist film; and
removing portions of the sacrificial hydrophilic material not covered by the EUV photoresist pattern after said utilizing EUV lithography to pattern the photoresist film and form the EUV photoresist pattern and before said selectively depositing the topcoat film on the EUV photoresist pattern;
wherein during said selectively depositing the topcoat film on the EUV photoresist pattern, the underlayer performs as the inhibition layer to prevent the topcoat film from being deposited on the exposed surfaces of the underlayer not covered by the EUV photoresist pattern.

18. The method of claim 17, wherein the underlayer comprises carbon (C) or silicon carbide (SiC), and wherein the sacrificial hydrophilic material comprises amorphous carbon (a-C), silicon oxycarbide (SiOC) or oxomethyl (CxOyHz, where 0≤x≤1, 0≤y≤1 and 0≤z≤1).

19. A method of forming an extreme ultra-violet (EUV) photoresist pattern on a semiconductor substrate, the method comprising:
depositing a photoresist film on an underlayer formed above the semiconductor substrate;
utilizing EUV lithography to pattern the photoresist film and form an EUV photoresist pattern on the underlayer, wherein the EUV photoresist pattern comprises a plurality of photoresist structures having a pitch that is variable between the photoresist structures;
selectively depositing an inhibition layer on exposed surfaces of the underlayer not covered by the EUV photoresist pattern; and
utilizing area selective deposition (ASD) to selectively deposit a topcoat film on the EUV photoresist pattern, wherein the inhibition layer prevents the topcoat film from being deposited on the exposed surfaces of the underlayer not covered by the EUV photoresist pattern regardless of the pitch between the photoresist structures.

20. The method of claim 19, wherein at least one of the photoresist film and the topcoat film contains an organometallic oxide.

21. The method of claim 20, wherein the organometallic oxide has a central metal atom of tin (Sn), titanium (Ti), zirconium (Zr), indium (In), antimony (Sb), bismuth (Bi), zinc (Zn), hafnium (Hf), aluminum (Al) or combinations thereof.

22. The method of claim 19, wherein the underlayer comprises a hydrophilic material having a water contact angle less than or equal to 60° and the inhibition layer comprises a hydrophobic material having a water contact angle greater than or equal to 90°.

23. The method of claim 22, wherein the underlayer comprises amorphous carbon (a-C), silicon oxycarbide (SiOC), amorphous silicon or silicon dioxide (SiO₂), and wherein the inhibition layer comprises materials having short chain molecules, materials having methyl end groups, benzene end groups or fluorocarbon end groups, and self-assembled monolayers (SAMs) having silane head groups, carboxylic head groups or phosphonic head groups.

24. The method of claim 19, wherein before said selectively depositing the inhibition layer, the method comprises:
exposing the semiconductor substrate to an ultra-violet (UV) treatment to enable selective adsorption of the inhibition layer on the exposed surfaces of the underlayer, rather than on the EUV photoresist pattern, during said selectively depositing the inhibition layer.

25. The method of claim 24, wherein said exposing the semiconductor substrate to the ultra-violet (UV) treatment comprises:
exposing the semiconductor substrate to UV radiation in the presence of an oxidizing species to form hydroxide groups on the exposed surfaces of the underlayer; and
wherein the inhibition layer reacts with the hydroxide groups to selectively adsorb on the exposed surfaces of the underlayer.
